(19) United States
(12) Patent Application Publication
(10) Pub. No.: US 2020/0027730 A1
(43) Pub. Date: Jan. 23, 2020

(54) FILM FORMING METHOD AND METHOD OF MANUFACTURING SEMICONDUCTOR DEVICE

(71) Applicants: Tatsuji NAGAOKA, Nagakute-shi (JP); Hiroyuki NISHINAKA, Kyoto-shi (JP); Masahiro YOSHIMOTO, Kyoto-shi (JP)

(72) Inventors: Tatsuji NAGAOKA, Nagakute-shi (JP); Hiroyuki NISHINAKA, Kyoto-shi (JP); Masahiro YOSHIMOTO, Kyoto-shi (JP)

(73) Assignees: TOYOTA JIDOSHA KABUSHIKI KAISHA, Toyota-shi (JP); NATIONAL UNIVERSITY CORPORATION KYOTO INSTITUTE OF TECHNOLOGY, Kyoto-shi (JP)

(21) Appl. No.: 16/512,442

(22) Filed: Jul. 16, 2019

(30) Foreign Application Priority Data
Jul. 17, 2018 (JP) 2018-134344

(51) Int. Cl. H01L 21/02; C30B 29/26; H01L 21/288

(52) U.S. Cl. CPC H01L 21/02565; C30B 29/26; H01L 21/288; H01L 21/0257; H01L 21/02628

(57) ABSTRACT

A film forming method of forming an oxide film on a substrate, wherein the oxide film has germanium doped therein and comprises a property of a conductor or a semiconductor, is disclosed herein. The film forming method may include supplying mist of a solution to a surface of the substrate while heating the substrate, wherein an oxide film material including a constituent element of the oxide film and an organic germanium compound may be dissolved in the solution.

### CROSS-REFERENCE TO RELATED APPLICATION

This application claims priority to Japanese Patent Application No. 2018-134344 filed on Jul. 17, 2018, the contents of which are hereby incorporated by reference into the present application.

### TECHNICAL FIELD

A technology disclosed herein relates to a technology of forming a film on a substrate.

### BACKGROUND

Japanese Patent Application Publication No. 2015-070248 discloses a technology of forming an oxide film on a surface of a substrate. This technology includes supplying mist of a solution in which an oxide film material and a dopant material are dissolved to the surface of the substrate while heating the substrate. According to this technology, an oxide film in which germanium has been added as a dopant can be grown on the surface of the substrate.

### SUMMARY

The technology in Japanese Patent Application Publication. No. 2015-070248 uses, as a dopant material, germanium oxide, germanium chloride, germanium bromide, germanium iodide, or the like. In this film forming method, an appropriate film forming condition changes depending on an amount of a supplied dopant, so it is difficult to accurately control electrical conductivity of the oxide film. Therefore, the disclosure herein proposes a technology capable of more accurately controlling electrical conductivity of an oxide film that has a property of a conductor or a semiconductor when the oxide film is formed.

In a film forming method disclosed herein, an oxide film that has germanium doped therein and comprises a property of a conductor or a semiconductor is formed on a substrate. This film forming method may comprise supplying mist of a solution to a surface of the substrate while heating the substrate. An oxide film material comprising a constituent element of the oxide film and an organic germanium compound may be dissolved in the solution.

In this film forming method, the organic germanium compound is used as a dopant material to form the oxide film in which germanium has been added. According to this film forming method, electrical conductivity of the oxide film can be controlled accurately.

### BRIEF DESCRIPTION OF DRAWING

FIG. 1 is a configuration diagram of a film forming device 10.

### DETAILED DESCRIPTION

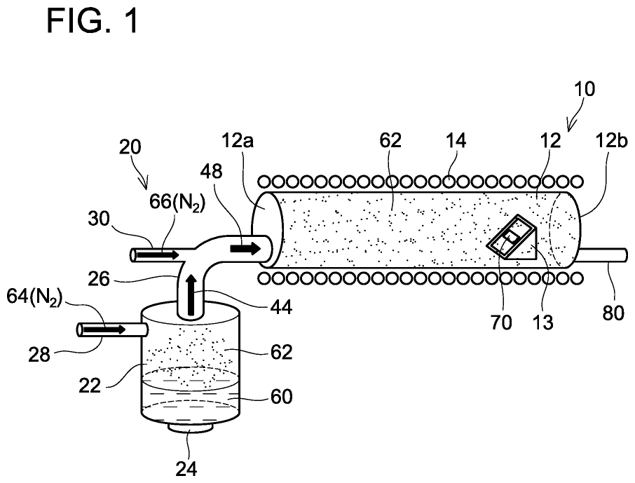

A film forming device 10 shown in FIG. 1 is a device configured to form an oxide film on a substrate 70. The film forming device 10 includes a furnace 12 in which the substrate 70 is placed, a heater 14 configured to heat the furnace 12, a mist supply device 20 connected to the furnace 12, and a discharge pipe 80 connected to the furnace 12.

A specific configuration of the furnace 12 is not limited particularly. As an example, the furnace 12 shown in FIG. 1 is a tubular furnace that extends from an upstream end 12a to a downstream end 12b. A cross section of the furnace 12, which is taken perpendicular to a longitudinal direction of the furnace 12, is circular. For example, a diameter of the furnace 12 may be set to approximately 40 mm. It should be noted that the cross section of the furnace 12 is not limited to a circular shape. The furnace 12 has its upstream end 12a connected to the mist supply device 20. The furnace 12 has its downstream end 12b connected to the discharge pipe 80.

In the furnace 12, a substrate stage 13 for supporting the substrate 70 is provided. The substrate stage 13 is configured to allow the substrate 70 to be tilted relative to the longitudinal direction of the furnace 12. The substrate 70 supported by the substrate stage 13 is supported in an orientation that exposes a surface of the substrate 70 to mist flowing in the furnace 12 from the upstream end 12a toward the downstream end 12b.

The heater 14 heats the furnace 12 as mentioned before. A specific configuration of the beater 14 is not limited particularly. As an example, the heater 14 shown in FIG. 1 is an electric heater and is arranged along an outer peripheral wall of the furnace 12. The heater 14 thus heats the outer peripheral wall of the furnace 12 and the substrate 70 in the furnace 12 is thereby heated.

The mist supply device 20 supplies, into the furnace 12, mist of a solution that includes a raw material of an oxide film. A specific configuration of the mist supply device 20 is not limited particularly. As an example, the mist supply device 20 shown in FIG. 1 includes a container 22 that accommodates a solution 60, an ultrasonic transducer 24 provided at the container 22, a mist supply path 26 that connects the container 22 and the furnace 12, a carrier gas introduction path 28 connected to the container 22, and a diluent gas introduction path 30 connected to the mist supply path 26. The carrier gas introduction path 28 supplies carrier gas 64 to the container 22. The diluent gas introduction path 30 supplies diluent gas 66 to the mist supply path 26. The ultrasonic transducer 24 applies ultrasonic vibrations to the solution 60 in the container 22 to generate mist 62 of the solution 60.

The discharge pipe 80 is connected to the downstream end 12b of the furnace 12. The mist 62 supplied into the furnace 12 by the mist supply device 20 flows through the furnace 12 to the downstream end 12b and is then discharged to an outside of the furnace 12 through the discharge pipe 80.

### First Embodiment

Next, a film forming method using the film forming device 10 will be described. In a first embodiment, a substrate constituted of β-gallium oxide (β-Ga₂O₃) single crystal having its (010) crystal plane exposed at a surface thereof is used as the substrate 70. Moreover, in the first embodiment, a β-gallium oxide film is formed on the surface of the substrate 70. Moreover, in the first embodiment, an aqueous solution in which gallium chloride (GaCl₃ or Ga₂Cl₆) and β-carboxyethyl germanium sesquioxide ((GeCH₂CH₂COOH)₂O₃) are dissolved is used as the solution 60. Gallium chloride is a raw material of the gallium oxide film. β-carboxyethyl germanium sesquioxide is an organic germanium compound used as a dopant material. In other words, in the first embodiment, the oxide film is a β-gallium oxide film, the oxide film material is gallium chloride, and the organic germanium compound is β-carboxyethyl germanium sesquioxide. In the solution 60, gallium chloride is dissolved at a concentration of 0.5 mol/L and β-carboxyethyl germanium sesquioxide is dissolved at a concentration of 1×10⁻⁴ mol/L. Moreover, in the first embodiment, nitrogen gas is used as the carrier gas 64 and nitrogen gas is used as the diluent gas 66.

As shown in FIG. 1, firstly, the substrate 70 is placed on the substrate stage 13 in the furnace 12. Here, the substrate 70 is placed on the substrate stage 13 in an orientation that allows a (010) crystal plane of the substrate 70 to be an upper surface (a surface to be exposed to the mist 62). Next, the substrate 70 is heated by the heater 14. Here, a temperature of the substrate 70 is controlled to be at approximately 750 degrees Celsius. When the temperature of the substrate 70 is stabilized, the mist supply device 20 is activated. In other words, the ultrasonic transducer 24 is activated to generate the mist 62 of the solution 60 in the container 22. At the same time, the carrier gas 64 is introduced into the container 22 from the carrier gas introduction path 28 and the diluent gas 66 is introduced into the mist supply path 26 from the diluent gas introduction path 30. Here, a total flow rate of the carrier gas 64 and the diluent gas 66 is set to approximately 5 L/min. The carrier gas 64 passes through the container 22 and flows into the mist supply path 26 as shown by an arrow 44. At this time, the mist 62 in the container 22 flows into the mist supply path 26 together with the carrier gas 64. Moreover, the diluent gas 66 is mixed with the mist 62 in the mist supply path 26. The mist 62 is thereby diluted. The mist 62 flows through the mist supply path 26 to a downstream side together with the nitrogen gas (i.e., the carrier gas 64 and the diluent gas 66) and flows from the mist supply path 26 into the furnace 12 as shown by an arrow 48. In the furnace 12, the mist 62 flows toward the downstream end 12b together with the nitrogen gas and is discharged to the discharge pipe 80.

A part of the mist 62 flowing in the furnace 12 adheres to the surface of the heated substrate 70. When this happens, the mist 62 (i.e., the solution 60) chemically reacts on the substrate 70. Consequently, β-gallium oxide (β-Ga₂O₃) is generated on the substrate 70. Since the mist 62 is continuously supplied to the surface of the substrate 70, a β-gallium oxide film is grown on the surface of the substrate 70. According to this film forming method, a high-quality, single-crystal β-gallium oxide film is grown. Germanium atoms in β-carboxyethyl germanium sesquioxide are incorporated in the β-gallium oxide film as a donor. Therefore, the β-gallium oxide film doped with germanium is formed. Here, the β-gallium oxide film is grown by performing the film forming process for 30 minutes with consumption of approximately 50 ml of the solution 60. When properties of the β-gallium oxide film formed by this film forming method were measured by Hall effect measurement, a carrier density of 6.5×10¹⁸ cm⁻³ and a mobility of 55 cm²/Vsec were observed.

According to the film forming method of the first embodiment, a β-gallium oxide film with high quality can be formed. In the first embodiment, in particular, a β-gallium oxide film is homoepitaxially grown on the substrate 70 constituted of β-gallium oxide, so a β-gallium oxide film with higher quality can be formed. Moreover, the organic germanium compound is used as a dopant material, so electrical conductivity of the β-gallium oxide film can be controlled accurately. With the homoepitaxial growth, in particular, more accurate control for electrical conductivity can be achieved.

### Second Embodiment

Next, a film forming method of a second embodiment will be described. In the second embodiment, a substrate constituted of sapphire (Al₂O₃) is used as the substrate 70. Moreover, in the second embodiment, an α-gallium oxide film is formed on the surface of the substrate 70. Moreover, in the second embodiment, an aqueous solution in which gallium bromide (GaBr₃, Ga₂Br₆) and β-carboxyethyl germanium sesquioxide ((GeCH₂CH₂COOH)₂O₃) are dissolved is used as the solution 60. Gallium bromide is a raw material of the gallium oxide film. β-carboxyethyl germanium sesquioxide is an organic germanium compound used as a dopant material. In other words, in the second embodiment, the oxide film is an α-gallium oxide film, the oxide film material is gallium bromide, and the organic germanium compound is β-carboxyethyl germanium sesquioxide. In the solution 60, gallium bromide is dissolved at a concentration of 0.1 mol/L and β-carboxyethyl germanium sesquioxide is dissolved at a concentration of 1×10⁻⁴ mol/L. Moreover, in the second embodiment, nitrogen gas is used as the carrier gas 64 and nitrogen gas is used as the diluent gas 66.

In the film forming method of the second embodiment as well, as in the first embodiment, the substrate 70 is placed on the substrate stage 13 and is heated by the heater 14. Here, the temperature of the substrate 70 is controlled to be at approximately 500 degrees Celsius. When the temperature of the substrate 70 is stabilized, the mist supply device 20 is activated. In other words, the ultrasonic transducer 24 is activated, the carrier gas 64 is introduced, and the diluent gas 66 is introduced in the same way as in the first embodiment. Consequently, the mist 62 flows into the furnace 12 and a part of the mist 62 flowing in the furnace 12 adheres to the surface of the heated substrate 70. When this happens, the mist 62 (i.e., the solution 60) chemically reacts on the substrate 70. Consequently, α-gallium oxide (α-Ga₂O₃) is generated on the substrate 70. Since the mist 62 is continuously supplied to the surface of the substrate 70, an α-gallium oxide film is grown on the surface of the substrate 70. According to this film forming method, a high-quality, single-crystal α-gallium oxide film is grown. Germanium atoms in β-carboxyethyl germanium sesquioxide are incorporated in the α-gallium oxide film as a donor. Therefore, the α-gallium oxide film doped with germanium is formed. According to the film forming method of the second embodiment, the organic germanium compound is used as a dopant material, so electrical conductivity of the α-gallium oxide film can be controlled accurately.

### Third Embodiment

Next, a film forming method of a third embodiment will be described. In the third embodiment, a substrate constituted of glass is used as the substrate 70. Moreover, in the third embodiment, a zinc oxide film (ZnO) is formed on the surface of the substrate 70. Moreover, in the third embodiment, an aqueous solution in which zinc acetate (Zn(Ac₂)₂: where Ac represents an acetyl group) and β-carboxyethyl germanium sesquioxide ((GeCH₂CH₂COOH)₂O₃) are dissolved is used as the solution 60. Zinc acetate is a raw material of the zinc oxide film. β-carboxyethyl germanium sesquioxide is an organic germanium compound used as a dopant material. In other words, in the third embodiment, the oxide film is a zinc oxide film, the oxide film material is zinc acetate, and the organic germanium compound is β-carboxyethyl germanium sesquioxide. In the solution 60, zinc acetate is dissolved at a concentration of 0.05 mol/L and β-carboxyethyl germanium sesquioxide is dissolved at a concentration of 1×10⁻⁴ mol/L. Moreover, in the third embodiment, nitrogen gas is used as the carrier gas 64 and nitrogen gas is used as the diluent gas 66.

In the film forming method of the third embodiment as well, as in the first embodiment, the substrate 70 is placed on the substrate stage 13. Next, the substrate 70 is heated by the heater 14. Here, the temperature of the substrate 70 is controlled to be at approximately 400 degrees Celsius. When the temperature of the substrate 70 is stabilized, the mist supply device 20 is activated. In other words, the ultrasonic transducer 24 is activated, the carrier gas 64 is introduced, and the diluent gas 66 is introduced in the same way as in the first embodiment. Consequently, the mist 62 flows into the furnace 12 and a part of the mist 62 flowing in the furnace 12 adheres to the surface of the heated substrate 70. When this happens, the mist 62 (i.e., the solution 60) chemically reacts on the substrate 70. Consequently, zinc oxide (ZnO) is generated on the substrate 70. Since the mist 62 is continuously supplied to the surface of the substrate 70, a zinc oxide film is grown on the surface of the substrate 70. According to this film forming method, a high-quality, single-crystal zinc oxide film is grown. Germanium atoms in β-carboxyethyl germanium sesquioxide are incorporated in the zinc oxide film as a donor. Therefore, the zinc oxide film doped with germanium is formed. According to the film forming method of the third embodiment, the organic germanium compound is used as a dopant material, so electrical conductivity of the zinc oxide film can be controlled accurately.

As described in each of the first to third embodiments, an oxide film doped with germanium can be formed by growing the oxide film by using mist of a solution in which an oxide film material including a constituent element of the oxide film and an organic germanium compound are dissolved. In a case where tin (Sn) is used as a donor, electrical conductivity of the oxide film cannot be controlled accurately because only tetravalent tin can function as a donor despite the fact that tin can have oxidation numbers II and IV. In this regard, tin can be made tetravalent by adding hydrochloric acid and/or hydrogen peroxide solution to a solution in which tin is dissolved. However, adding hydrochloric acid and/or hydrogen peroxide solution to the solution causes a decrease in growth rate of the oxide film. In contrast to this, with germanium used as a donor as in the first to third embodiments, electrical conductivity of the oxide film can be controlled relatively accurately, without adding hydrochloric acid and/or hydrogen peroxide solution to a germanium solution. Using the organic germanium compound as a dopant material, in particular, enables electrical conductivity of the oxide film to be controlled more accurately. Therefore, according to each of the film forming methods of the first to third embodiments, an oxide film can be grown at a high film forming rate while electrical conductivity of the oxide film is controlled accurately. Manufacturing a semiconductor device (e.g., a diode, a transistor, or the like) with an oxide film formed according to the first to third embodiments, enables the semiconductor device to have good properties.

Moreover, in each of the first and second embodiments described above, a number (concentration) of germanium atoms dissolved in the solution 60 is ten times or less a number (concentration) of gallium atoms dissolved in the solution 60. According to this constitution, a gallium oxide film with high crystal quality can be formed. Moreover, in the third embodiment described above, a number (concentration) of germanium atoms dissolved in the solution 60 is ten times or less a number (concentration) of zinc atoms dissolved in the solution 60. According to this constitution, a zinc oxide film with high crystal quality can be formed.

Moreover, in the first to third embodiments described above, the substrate 70 is heated to 400 to 750 degrees Celsius. In the film forming step, the temperature of the substrate 70 can be controlled to be 400 to 1000 degrees Celsius. Controlling the temperature as such enables a gallium oxide film and a zinc oxide film to be formed more suitably.

In the first to third embodiments, a gallium oxide film (Ga₂O₃) or a zinc oxide film (ZnO) is formed on the surface of the substrate 70. However, another oxide film may be formed on the surface of the substrate 70. For example, an indium oxide film (In₂O₃) or an aluminum oxide film (Al₂O₃) may be formed. Moreover, a film constituted of a compound material of indium oxide, aluminum oxide, and gallium oxide (i.e., InₓAl_{y}Ga_{z}O₃ (0≤x≤2, 0≤y≤2, 0≤z≤2)) may be formed. In a case where an indium oxide film is formed, an indium compound can be used as the oxide film material to be dissolved in the solution 60. In a case where an aluminum oxide film is formed, an aluminum compound can be used as the oxide film material to be dissolved in the solution 60. In a case where a film constituted of a compound material of indium oxide, aluminum oxide, and gallium oxide is formed, a combination of an indium compound, an aluminum compound, and a gallium compound can be used as the oxide film material to be dissolved in the solution 60. In these cases, oxide films with high crystallinity can be formed by setting a number (i.e., molarity) of germanium atoms included in the mist 62 to be ten times or less a total number of indium atoms, aluminum atoms, and gallium atoms included in the mist 62 (i.e., a sum of molarities of indium atoms, aluminum atoms, and gallium atoms).

Moreover, in each of the first to third embodiments described above, a single-crystal oxide film is formed. However, an amorphous or polycrystalline oxide film may be formed.

Moreover, in the first to third embodiments described above, the substrate 70 is constituted of β-gallium oxide, sapphire, or glass. However, the substrate 70 may be constituted of another material. Using the substrate 70 constituted of another material can form an oxide film having a property different from those of the first to third embodiments. For example, the substrate 70 may be constituted of α-gallium oxide (α-Ga₂O₃), γ-gallium oxide, δ-gallium oxide, ε-gallium oxide, aluminum oxide (e.g., α-aluminum oxide (α-Al₂O₃)), gallium nitride (GaN), or the like. Moreover, the substrate 70 may be an insulator, a semiconductor, or a conductor.

Moreover, in each of the first to third embodiments described above, an oxide film is formed on the surface of the substrate 70 (i.e., on a plate-shaped member). However, a member having another shape may be used as a base and an oxide film may be formed on a surface of the base.

Moreover, in the first to third embodiments described above, the organic germanium compound dissolved in the solution 60 is β-carboxyethyl germanium sesquioxide. However, another material may be used as the organic germanium compound to be dissolved in the solution 60. In order to form a high-quality gallium oxide film, the organic germanium compound may be a metal complex. For example, isobutylgermane ((Me₂CHCH₂)GeH₃: where Me represents a methyl group), tris(trimethylsilyl)germanium hydride ((Me₃Si)₃GeH: where Me represents a methyl group), propagermanium (C₆H₁₀O₇Ge₂), or the like can be used as the organic germanium compound. It should be noted that β-carboxyethyl germanium sesquioxide is more easily used because it is inexpensive and highly safe.

Moreover, in the first and second embodiments described above, the gallium compound dissolved in the solution 60 is gallium chloride or gallium bromide. However, another material may be used as the gallium compound to be dissolved in the solution 60. In order to form a high-quality gallium oxide film, the gallium compound may be organic matter. Moreover, the gallium compound may be a metal complex. Alternatively, the gallium compound may be a halide. For example, gallium acetylacetonate (e.g., gallium (III) acetylacetonate (C₁₅H₂₁GaO₆)), gallium triacetate (C₆H₉GaO₆), gallium iodide (GaI₃, Ga₂I₆), or the like can be used as the gallium compound. It should be noted that gallium chloride (gallium (III) chloride, in particular) is more easily used because it is inexpensive and enables film formation with fewer residual impurities.

Moreover, in the third embodiment described above, the zinc compound dissolved in the solution 60 is zinc acetate. However, another material may be used as the zinc compound to be dissolved in the solution 60.

Moreover, in the first to third embodiments, the container 22 accommodates the solution 60 in which both of the oxide film material and the organic germanium compound are dissolved, the mist is generated from the solution 60 and the generated mist is supplied to the furnace 12. However, a first container that accommodates a solution in which the oxide film material is dissolved and a second container that accommodates a solution in which the organic germanium compound is dissolved may be separately provided. Then, first mist of the solution in which the oxide film material is dissolved may be generated in the first container, second mist of the solution in which the organic germanium compound is dissolved may be generated in the second container, and the first mist and the second mist may be supplied to the furnace 12.

Moreover, in the first to third embodiments, nitrogen is used as the carrier gas 64 and the diluent gas 66. However, another gas such as inert gas can be used as the carrier gas 64 and the diluent gas 66.

Some of the features characteristic to the disclosure herein will be listed below. It should be noted that the respective technical elements are independent of one another, and are useful solely or in combinations.

In an example of film forming method disclosed herein, supplying mist of a solution in which an oxide film material and an organic germanium compound are dissolved to a surface of a substrate may comprise generating the mist from the solution in which the oxide film material and the organic germanium compound are dissolved; and supplying the mist of the solution in which the oxide film material and the organic germanium compound are dissolved to the surface of the substrate.

In another example of film forming method disclosed herein, supplying mist of a solution in which an oxide film material and an organic germanium compound are dissolved to a surface of a substrate may comprise generating mist from a solution in which the oxide film. material is dissolved; generating mist from a solution in which the organic germanium compound is dissolved; and supplying the mist of the solution in which the oxide film material is dissolved and the mist of the solution in which the organic germanium compound is dissolved to the surface of the substrate.

As above, the oxide film can suitably formed by any one of the method in which the mist is generated from the solution in which both the oxide film material and the organic germanium compound are dissolved and the method in which the mists are generated respectively from the solution in which the oxide film material is dissolved and the solution in which the organic germanium compound is dissolved.

In an example of film forming method disclosed herein, the oxide film may be a single-crystal film.

Forming a single-crystal oxide film enables the oxide film to be suitably used in a semiconductor element and the like.

In an example of film forming method disclosed herein, the organic germanium compound may be a metal complex.

In an example of film forming method disclosed herein, the organic germanium compound may be β-carboxyethyl germanium sesquioxide.

In an example of film forming method disclosed herein, the oxide film may be constituted of indium oxide, aluminum oxide, gallium oxide, or compound oxide thereof. In this case, the oxide film material may comprise at least one of an indium compound, an aluminum compound, and a gallium compound.

In an example of film forming method disclosed herein, the oxide film may be constituted of zinc oxide. In this case, the oxide film material may comprise a zinc compound.

In an example of film forming method disclosed herein, the oxide film may be constituted of gallium oxide or oxide comprising gallium oxide. In this case, the oxide film material may comprise a gallium compound.

In an example of film forming method disclosed herein, the gallium compound may be organic matter.

In an example of film forming method disclosed herein, the gallium compound may be a metal complex.

In an example of film forming method disclosed herein, the gallium compound may be gallium acetylacetonate.

In an example of film forming method disclosed herein, the gallium compound may be a halide.

In an example of film forming method disclosed herein, the gallium compound may be gallium chloride.

Gallium chloride is inexpensive and less likely causes residual impurities. Therefore, it is useful as the oxide film material.

In an example of film forming method disclosed herein, a number of germanium atoms included in the mist of the solution in which the oxide film material and the organic germanium compound are dissolved is ten times or less a total number of indium atoms, aluminum atoms, and gallium atoms included in the mist of the solution in which the oxide film material and the organic germanium compound are dissolved.

According to the above configuration, an oxide film with high crystal quality can be formed.

In an example of film forming method disclosed herein, the substrate may be constituted of gallium oxide.

In an example of film forming method disclosed herein, the substrate may be constituted of β-Ga₂O₃.

In an example of film forming method disclosed herein, the substrate may be constituted of α-Ga₂O₃.

In an example of film forming method disclosed herein, the substrate may be constituted of α-Al₂O₃.

In an example of film forming method disclosed herein, the oxide film may be constituted of β-Ga₂O₃.

According to the above configuration, properties of the oxide film are stable and electrical conductivity of the oxide film can be easily controlled.

In an example of film forming method disclosed herein, the substrate may be heated to 400 to 1000 degrees Celsius when the oxide film is formed.

According to the above configuration an oxide film with high crystal quality can be formed and electrical conductivity of the oxide film can be controlled accurately.

While specific examples of the present disclosure have been described above in detail, these examples are merely illustrative and place no limitation on the scope of the patent claims. The technology described in the patent claims also encompasses various changes and modifications to the specific examples described above. The technical elements explained in the present description or drawing provide technical utility either independently or through various combinations. The present disclosure is not limited to the combinations described at the time the claims are filed. Further, the purpose of the examples illustrated by the present description or drawing is to satisfy multiple objectives simultaneously, and satisfying any one of those objectives gives technical utility to the present disclosure.

What is claimed is:

1. A film forming method of forming an oxide film on a substrate, wherein the oxide film has germanium doped therein and comprises a property of a conductor or a semiconductor, the film forming method comprising:
supplying mist of a solution to a surface of the substrate while heating the substrate, wherein an oxide film material comprising a constituent element of the oxide film and an organic germanium compound are dissolved in the solution.

2. The film forming method of claim 1, wherein
the supply of the mist to the surface of the substrate comprises:
generating the mist from the solution in which the oxide film material and the organic germanium compound are dissolved; and
supplying the mist of the solution in which the oxide film material and the organic germanium compound are dissolved to the surface of the substrate.

3. The film forming method of claim 1, wherein
the supply of the mist to the surface of the substrate comprises:
generating mist from a solution in which the oxide film material is dissolved;
generating mist from a solution in which the organic germanium compound is dissolved; and
supplying the mist of the solution in which the oxide film material is dissolved and the mist of the solution in which the organic germanium compound is dissolved to the surface of the substrate.

4. The film forming method of claim 1, wherein the oxide film is a single-crystal film.

5. The film forming method of claim 1, wherein the organic germanium compound is a metal complex.

6. The film forming method of claim 1, wherein the organic germanium compound is β-carboxyethyl germanium sesquioxide.

7. The film forming method of claim 1, wherein
the oxide film is constituted of indium oxide, aluminum oxide, gallium oxide, or compound oxide thereof, and
the oxide film material comprises at least one of an indium compound, an aluminum compound, and a gallium compound.

8. The film forming method of claim 1, wherein
the oxide film is constituted of zinc oxide, and
the oxide film material comprises a zinc compound.

9. The film forming method of claim 1, wherein
the oxide film is constituted of gallium oxide or oxide comprising gallium oxide, and
the oxide film material comprises a gallium compound.

10. The film forming method of claim 9, wherein the gallium compound is organic matter.

11. The film forming method of claim 9, wherein the gallium compound is a metal complex.

12. The film forming method of claim 9, wherein the gallium compound is gallium acetylacetonate.

13. The film forming method of claim 9, wherein the gallium compound is a halide.

14. The film forming method of claim 9, wherein the gallium compound is gallium chloride.

15. The film forming method of claim 1, wherein a number of germanium atoms included in the mist of the solution in which the oxide film material and the organic germanium compound are dissolved is ten times or less a total number of indium atoms, aluminum atoms, and gallium atoms included in the mist of the solution in which the oxide film material and the organic germanium compound are dissolved.

16. The film forming method of claim 1, wherein the substrate is constituted of gallium oxide.

17. The film forming method of claim 16, wherein the substrate is constituted of β-Ga₂O₃.

18. The film forming method of claim 16, wherein the substrate is constituted of α-Ga₂O₃.

19. The film forming method of claim 1, wherein the substrate is constituted of α-Al₂O₃.

20. The film forming method of claim 1, wherein the oxide film is constituted of β-Ga₂O₃.

21. The film forming method of claim 1, wherein the substrate is heated to 400 to 1000 degrees Celsius when the oxide film is formed.

22. A manufacturing method of a semiconductor device, the manufacturing method comprising forming the oxide film by the film forming method of claim 1.
